(19) United States
(12) Patent Application Publication
(10) Pub. No.: US 2023/0366121 A1
(43) Pub. Date: Nov. 16, 2023

(54) METHOD OF PREPARING SINGLE CRYSTAL PEROVSKITE ON FLEXIBLE SUBSTRATE

(71) Applicant: EWHA UNIVERSITY-INDUSTRY COLLABORATION FOUNDATION, Seoul (KR)

(72) Inventors: William JO, Seoul (KR); Yun Ae CHO, Namyangju-si (KR); Hye Ri JUNG, Pohang-si (KR)

(21) Appl. No.: 18/360,892

(22) Filed: Jul. 28, 2023

Related U.S. Application Data
(63) Continuation of application No. PCT/KR2022/001348, filed on Jan. 26, 2022.

(30) Foreign Application Priority Data
Jan. 28, 2021 (KR) 10-2021-0012625
Jan. 20, 2022 (KR) 10-2022-0008370

(51) Int. Cl. C30B 7/06; C30B 29/32

(52) U.S. Cl. CPC C30B 7/06; C30B 29/32

(57) ABSTRACT

The present disclosure relates to a method of preparing a single crystal perovskite on a flexible substrate.

### CROSS-REFERENCE TO RELATED APPLICATIONS

This application is a continuation of PCT Application No. PCT/KR2022/001348, filed on Jan. 26, 2022, which claims priorities to Korean Patent Applications No. 10-2021-0012625 filed on Jan. 28, 2021, and No. 10-2022-0008370 filed on Jan. 20, 2022, all of which are hereby incorporated by reference in their entirety.

### TECHNICAL FIELD

The present disclosure relates to a method of preparing a single crystal perovskite on a flexible substrate.

### BACKGROUND

A conventional single crystal halide perovskite material has a basic structure in the form of a thin film. However, the halide perovskite thin film is weak in terms of material stability. Single crystal halide perovskite has higher material stability and higher charge transport ability than thin film-type perovskite. However, single crystal halide perovskite produced in initial research stages has a relatively large thickness in millimeters.

Accordingly, in recent years, various studies for preparing single crystal halide perovskite having a small thickness have been conducted to improve device applicability and degree of integration, and some studies have proposed a method of preparing single crystal halide perovskite having a small thickness by using a glass substrate as a cover. The method of preparing single crystal halide perovskite having a small thickness by using a glass substrate includes a method of dropping a small amount of a precursor solution on a glass substrate and raising the temperature, and a method of dropping a small amount of a precursor solution on a glass substrate and putting a glass cover thereon. However, when a glass substrate is used, it is difficult to apply the prepared single crystal halide perovskite to a flexible device and the glass substrate used as a cover needs to have lower hydrophilicity than the bottom glass substrate. Thus, it is necessary to perform a separate process and it takes 1 to 2 days or longer for single crystals to grow, which results in a long processing time.

### Prior Art Document

### Non-Patent Literature

Yu et. al., “Single crystal hybrid perovskite field-effect transistors”, Nat. Commun. 2018, 9, 5354.

### DISCLOSURE OF THE INVENTION

### Problems to be Solved by the Invention

The present disclosure provides a method of preparing a single crystal perovskite on a flexible substrate.

However, problems to be solved by the present disclosure are not limited to the above-described problems, and although not described herein, other problems to be solved by the present disclosure can be clearly understood by those skilled in the art from the following descriptions.

### Means for Solving the Problems

A first aspect of the present disclosure provides a method of preparing a single crystal perovskite, including: applying a perovskite precursor solution onto a flexible substrate; covering the perovskite precursor solution with a polymer cover; and heat treating the perovskite precursor solution to grow the single crystal perovskite.

A second aspect of the present disclosure provides a single crystal perovskite prepared by the method according to the first aspect.

### Effects of the Invention

A method of preparing a single crystal perovskite according to embodiments of the present disclosure relates to a method of preparing a single crystal perovskite on a flexible substrate by using a polymer cover. The use of the polymer cover enables an increase in adhesion between the single crystal perovskite and the flexible substrate.

In the method of preparing a single crystal perovskite according to the embodiments of the present disclosure, single crystal perovskite is grown in a vacuum oven, and, thus, it is possible to shorten the processing procedure and processing time. Therefore, it is possible to solve a problem of a long processing time for preparing conventional single crystal perovskite having a small thickness.

The single crystal perovskite according to the embodiments of the present disclosure is formed on the flexible substrate. Thus, high photoreactivity and device stability can be maintained even when the single crystal perovskite is bent or cracked. Therefore, it is possible to apply the single crystal perovskite to a flexible device.

The single crystal perovskite according to the embodiments of the present disclosure is formed to a small thickness of about 0.5 µm to about 20 µm on the flexible substrate. Thus, the single crystal perovskite can be used to make a device and increase the degree of integration of the device.

### BRIEF DESCRIPTION OF THE DRAWINGS

FIG. 1 is a schematic diagram showing a method of preparing a single crystal perovskite in an example of the present disclosure.

FIG. 2A to FIG. 2D are photographs of single crystal CH₃NH₃PbBr₃ halide perovskite grown on flexible polyimide (PI) (FIG. 2A), polydimethylsiloxane (PDMS) (FIG. 2B), polytetrafluoroethylene (PTFE) (FIG. 2C), and polyethylene naphthalate (PEN) (FIG. 2D) substrates, respectively, in an example of the present disclosure.

FIG. 3A(i) to FIG. 3D(ii) are micrographs of single crystal CH₃NH₃PbBr₃ halide perovskite grown on flexible PI (FIG. 3A(i) and FIG. 3A(ii)), PDMS (FIG. 3B(i) and FIG. 3B(ii)), PTFE (FIG. 3C(i) and FIG. 3C(ii)), and PEN (FIG. 3D(i) and FIG. 3D(ii)) substrates, respectively, in an example of the present disclosure.

FIG. 4A(i), FIG. 4B(i), and FIG. 4C(i) are topographic images of single crystal CH₃NH₃PbBr₃ halide perovskite grown on flexible PI, PEN and PDMS substrates, respectively, and FIG. 4A(ii), FIG. 4B(ii), and FIG. 4C(ii) are the thickness profiles for each line of FIG. 4A(i), FIG. 4B(i), and FIG. 4C(i), respectively, in an example of the present disclosure.

FIG. 5 is a photograph of single crystal CH₃NH₃PbBr₃ halide perovskite grown on a flexible PI substrate in an example of the present disclosure.

FIG. 6A(i) and FIG. 6A(ii) are micrographs of single crystal CH₃NH₃PbBr₃ halide perovskite grown on a flexible PI substrate under forward light conditions, and FIG. 6B(i) and FIG. 6B(ii) are micrographs of single crystal CH₃NH₃PbBr₃ halide perovskite grown on a flexible PI substrate under forward backlight conditions, respectively, in an example of the present disclosure.

FIG. 7 and FIG. 8 show the X-ray diffraction (XRD) analysis result and the photoluminescence (PL) spectroscopy analysis result, respectively, of single crystal CH₃NH₃PbBr₃ halide perovskite grown on a flexible PI substrate in an example of the present disclosure.

FIG. 9A and FIG. 9B show a micrograph showing a tip contact with single crystal perovskite and a schematic diagram for assessment of optoelectronic properties of crystal perovskite, respectively, in an example of the present disclosure.

FIG. 9C to FIG. 9F show results of assessment of optoelectronic properties of single crystal CH₃NH₃PbBr₃ halide perovskite grown on a flexible PI substrate in an example of the present disclosure, and specifically show a light intensity-dependent light on/off graph at a voltage of 2 V (FIG. 9C), a voltage-dependent photocurrent graph (FIG. 9D), a light source power-dependent photocurrent and responsivity graph (FIG. 9E), and a light on/off graph (1 cycle) at a light intensity of 5 µW (FIG. 9F).

FIG. 10A and FIG. 10B are a schematic diagram (FIG. 10A) and a photograph (FIG. 10B) each showing that single crystal CH₃NH₃PbBr₃ halide perovskite grown on a flexible PI substrate is bent, and FIG. 10C shows a measurement graph showing PL depending on the bending angle, in an example of the present disclosure.

### BEST MODE FOR CARRYING OUT THE INVENTION

Hereinafter, embodiments and examples of the present disclosure will be described in detail with reference to the accompanying drawings so that the present disclosure may be readily implemented by those skilled in the art. However, it is to be noted that the present disclosure is not limited to the embodiments and examples but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the other element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document, the term “alkyl” or “alkyl group” may individually include linear or branched alkyl groups having 1 to 12 carbon atoms, 1 to 10 carbon atoms, 1 to 8 carbon atoms, or 1 to 5 carbon atoms, and all the possible isomers thereof. For example, the alkyl or alkyl group may individually include methyl group (Me), ethyl group (Et), n-propyl group (ⁿPr), iso-propyl group (ⁱPr), n-butyl group (ⁿBu), iso-butyl group (ⁱBu), tert-butyl group (^{t}Bu), sec-butyl group (^{s}Bu), n-pentyl group (ⁿPe), iso-pentyl group (ⁱPe), sec-pentyl group (^{s}Pe), tert-pentyl group (^{t}Pe), n-hexyl group, iso-hexyl group, heptyl group, 4,4-dimethyl pentyl group, octyl group, 2,2,4-trimethyl pentyl group, nonyl group, decyl group, undecyl group, dodecyl group, and isomers thereof, but may not be limited thereto.

In the following description, exemplary embodiments of the present disclosure will be described in detail, but the present disclosure may not be limited thereto.

A first aspect of the present disclosure provides a method of preparing a single crystal perovskite, including: applying a perovskite precursor solution onto a flexible substrate; covering the perovskite precursor solution with a polymer cover; and heat treating the perovskite precursor solution to grow the single crystal perovskite.

In an embodiment of the present disclosure, the perovskite may be halide perovskite having an AMX₃ structure. In an embodiment of the present disclosure, A in the AMX₃ structure may be an organic cation such as of CH₃NH₃ or HC(NH₂)₂; M may be Pb, Sn, Cu, Ni, Co, Fe, Mn, Pd, Cd, Ge, Cs or Eu; and X may be a halide.

In an embodiment of the present disclosure, the perovskite precursor solution may include AM powder, MX₂ powder, and an organic solvent. In an embodiment of the present disclosure, the organic solvent may include at least one selected from N,N-dimethylformamide (DMF), dimethyl sulfoxide (DMSO), γ-butyrolactone (GBL), dichlorobenzene (DCB) and toluene, but may not be limited thereto.

In an embodiment of the present disclosure, the applying the perovskite precursor solution onto the flexible substrate may include dropping the perovskite precursor solution onto the flexible substrate in an amount of about 1 µL to about 10 µL, but may not be limited thereto. In an embodiment of the present disclosure, the applying the perovskite precursor solution onto the flexible substrate may include dropping the perovskite precursor solution onto the flexible substrate in an amount of about 1 µL to about 10 µL, about 1 µL to about 8 µL, about 1 µL to about 6 µL, about 3 µL to about 10 µL, about 3 µL to about 8 µL, or about 3 µL to about 6 µL,but may not be limited thereto.

In an embodiment of the present disclosure, the flexible substrate may include at least one selected from polyimide(PI), polydimethylsiloxane (PDMS), polytetrafluoroethylene(PTFE), polyethylene naphthalate(PEN), polyethylene terephthalate(PET), and polyvinylidene-chloride(PVDC), but may not be limited thereto.

In the method of preparing the single crystal perovskite according to an embodiment of the present disclosure, the size and particle shape of the single crystal perovskite may vary depending on the type of the flexible substrate.

In an embodiment of the present disclosure, when the single crystal perovskite is prepared on the flexible polyimide (PI) substrate, the degree of binding between the flexible PI substrate and the single crystal perovskite is most desirable, washing and handling process is easy, and the resulting single crystal perovskite can have many applications as a device.

In an embodiment of the present disclosure, the flexible substrate may include a spacer formed on the flexible substrate. In an embodiment of the present disclosure, the spacer serves as a frame for growing the single crystal perovskite and may determine the thickness and/or area of the single crystal perovskite.

In an embodiment of the present disclosure, the spacer is not particularly limited as long as it is a hydrophobic material, but may not be limited thereto. In an embodiment of the present disclosure, the spacer may include at least one selected from polyimide(PI), polydimethylsiloxane (PDMS), polytetrafluoroethylene(PTFE), polyethylene naphthalate(PEN), polyethylene terephthalate(PET), and polyvinylidene-chloride(PVDC), but may not be limited thereto.

In an embodiment of the present disclosure, the polymer cover may include at least one selected from polyimide(PI), polydimethylsiloxane (PDMS), polytetrafluoroethylene(PTFE), polyethylene naphthalate(PEN), polyethylene terephthalate(PET), and polyvinylidene-chloride(PVDC), but may not be limited thereto.

In an embodiment of the present disclosure, the method may further include applying a pressure to the polymer cover before the heat treating. For example, a glass substrate may be placed on the polymer cover to apply a pressure onto the polymer cover.

In an embodiment of the present disclosure, the heat treating may be performed in a temperature range of about 60° C. to about 100° C. In an embodiment of the present disclosure, the heat treating may be performed in a temperature range of about 60° C. to about 100° C., about 70° C. to about 100° C., about 75° C. to about 100° C., about 60° C. to about 90° C., about 70° C. to about 90° C., about 75° C. to about 90° C., about 60° C. to about 85° C., about 70° C. to about 85° C., or about 75° C. to about 85° C.

In an embodiment of the present disclosure, the heat treating may be performed in a pressure range of about 0.5 bar to about 1 bar. In an embodiment of the present disclosure, the heat treating may be performed in a pressure range of about 0.5 bar to about 1 bar, about 0.6 bar to about 1 bar, about 0.7 bar to about 1 bar, about 0.8 bar to about 1 bar, or about 0.9 bar to about 1 bar.

In an embodiment of the present disclosure, the heat treating is performed in the above-described temperature range and pressure range, and, thus, the time required for the heat treating (i.e., the time required for growing the single crystal perovskite) can be reduced. In an embodiment of the present disclosure, the heat treating time may be about 1 hour to about 10 hours, but may not be limited thereto. In an embodiment of the present disclosure, the heat treating time may be about 1 hour to about 10 hours, about 2 hours to about 10 hours, about 3 hours to about 10 hours, about 1 hour to about 8 hours, about 2 hours to about 8 hours, about 3 hours to about 8 hours, about 1 hour to about 6 hours, about 2 hours to about 6 hours, about 3 hours to about 6 hours, about 1 hour to about 5 hours, about 2 hours to about 5 hours, or about 3 hours to about 5 hours, but may not be limited thereto.

In an embodiment of the present disclosure, the method of preparing the single crystal perovskite can be applied to the preparation of single crystal halide perovskite. In an embodiment of the present disclosure, the method of preparing the single crystal perovskite can also be applied to the preparation of two-dimensional halide perovskite.

A second aspect of the present disclosure provides a single crystal perovskite prepared by the method according to the first aspect.

Detailed descriptions of parts of the second aspect, which overlap with those of the first aspect, are omitted hereinafter, but the descriptions of the first aspect of the present disclosure may be identically applied to the second aspect of the present disclosure, even though they are omitted hereinafter.

In an embodiment of the present disclosure, the single crystal perovskite is formed on the flexible substrate, and, thus, high photoreactivity and device stability can be maintained even when the single crystal perovskite is bent or cracked. In an embodiment of the present disclosure, the single crystal perovskite is formed on the flexible substrate and thus can be applied to a flexible device.

In an embodiment of the present disclosure, the single crystal perovskite may include at least one selected from CH₃NH₃Pbl₃, CH₃NH₃PbBr₃, HC(NH₂)₂PbBr₃, HC(NH₂)₂Pbl₃, CH₃NH₃PbCl₃, HC(NH₂)₂PbCl₃, CsPbl₃, CsPbCl₃, CsPbBr₃, HC(NH₂)₂SnBr₃, HC(NH₂)₂SnBr₃, HC(NH₂)₂SnBr₃, CH₃NH₃SnBr₃, CH₃NH₃SnBr₃, and CH₃NH₃SnBr₃. In an embodiment of the present disclosure, the single crystal perovskite may be a single crystal halide perovskite.

In an embodiment of the present disclosure, the single crystal perovskite may have a crystal size of about 5 µm to about 300 µm. In an embodiment of the present disclosure, the single crystal perovskite may have a crystal size of about 5 µm to about 300 µm, about 5 µm to about 250 µm, or about 5 µm to about 200 µm.

In an embodiment of the present disclosure, the single crystal perovskite may have a thickness of about 0.5 µm to about 20 µm. In an embodiment of the present disclosure, the thickness of the single crystal perovskite may be determined by the thickness of the spacer.

In an embodiment of the present disclosure, the shape, size and/or thickness of the grown single crystal perovskite may be determined by the type of the flexible substrate.

In an embodiment of the present disclosure, the single crystal perovskite prepared by the preparation method may have a thickness of about 0.5 µm to about 20 µm, and may be bent at an angle of about 5° to about 60°.

### MODE FOR CARRYING OUT THE INVENTION

Hereinafter, the present disclosure will be described in more detail with reference to Examples, but the present disclosure may not be limited thereto.

### Examples

### <Example 1: Preparation of Single Crystal CH₃NH₃PbBr₃ Halide Perovskite on Flexible Substrate>

1) A polymer sheet of PI, PEN, PTFE or PDMS as a flexible substrate was placed on glass, and a spacer formed of PTFE was placed thereon to form a 1 cm × 1 cm frame.

2) 4 µL of a single crystal CH₃NH₃PbBr₃ halide perovskite precursor solution was dropped into the frame of 1), covered with a polymer cover (PDMS), and then pressed with a glass cover. Herein, the single crystal CH₃NH₃PbBr₃ halide perovskite precursor solution was prepared by dissolving lead(II) bromide (PbBr₂) (1 M) and methylammonium bromide (MABr) (1 M) at a molar ratio of 1:1 in 3 mL of dimethylformamide (DMF).

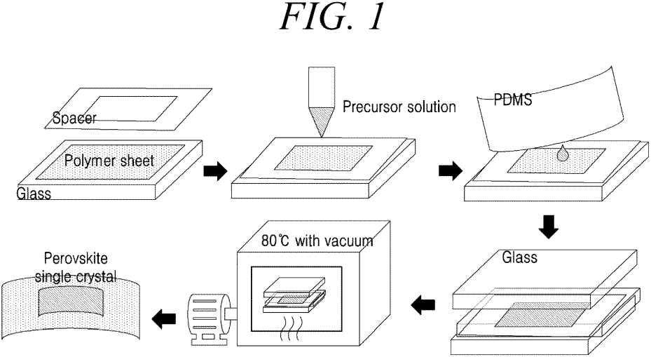

3) Crystals were grown in a vacuum oven at 80° C. in a vacuum state for 3 hours, and PDMS, the spacer and the glass cover were removed to obtain single crystal halide perovskite on the flexible substrate (FIG. 1).

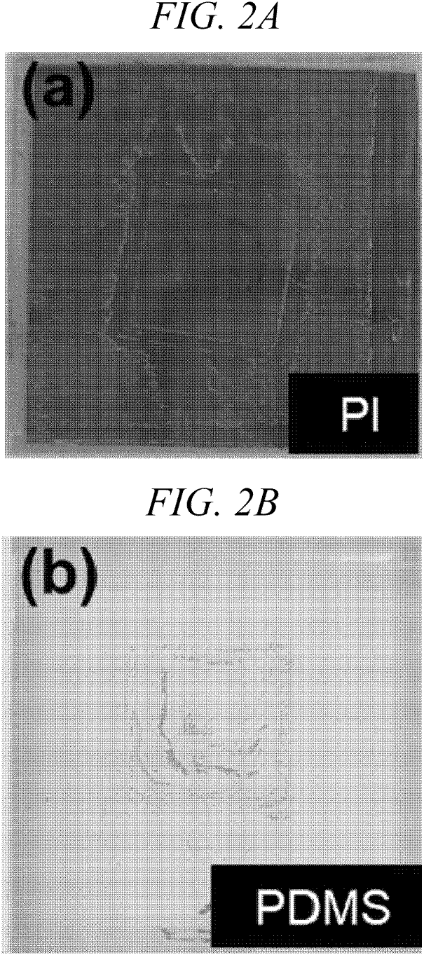

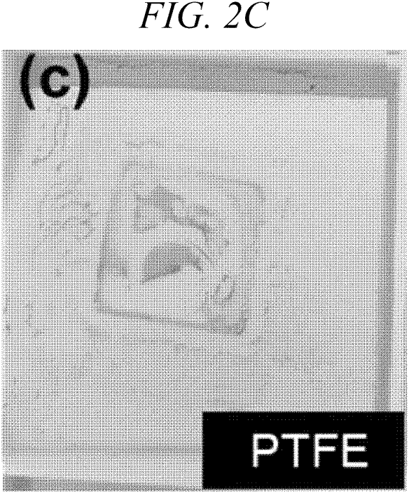

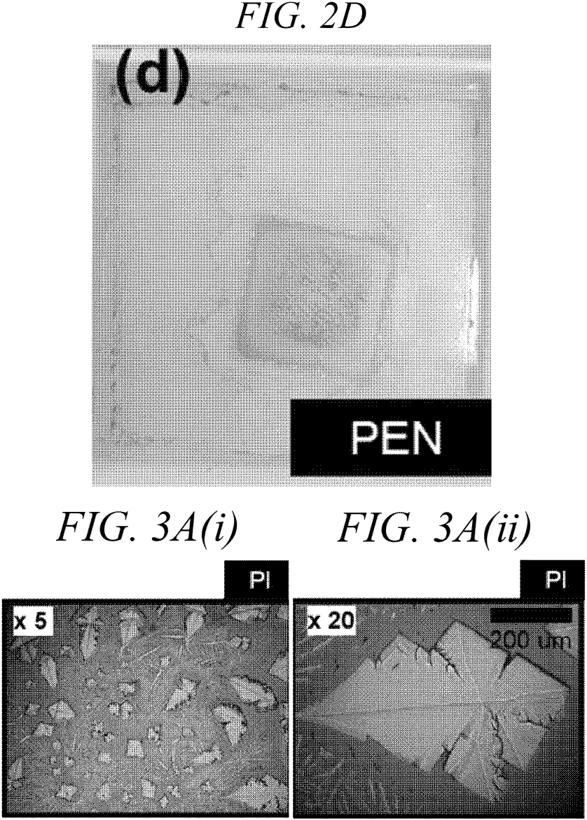

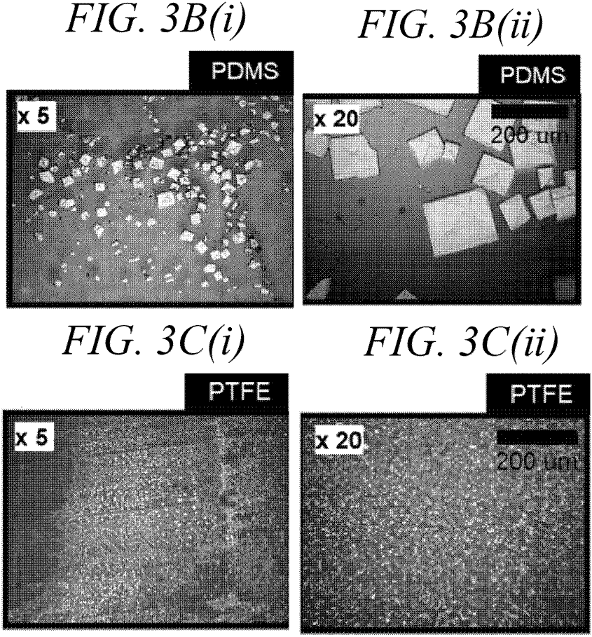

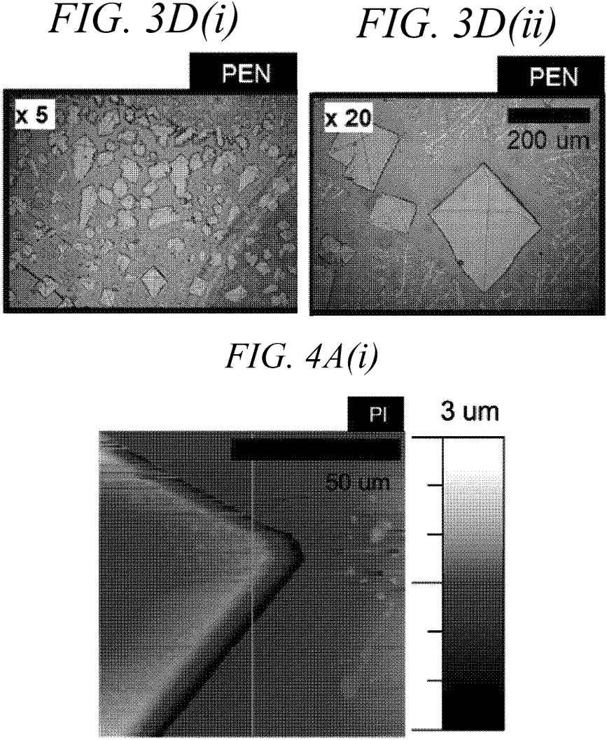

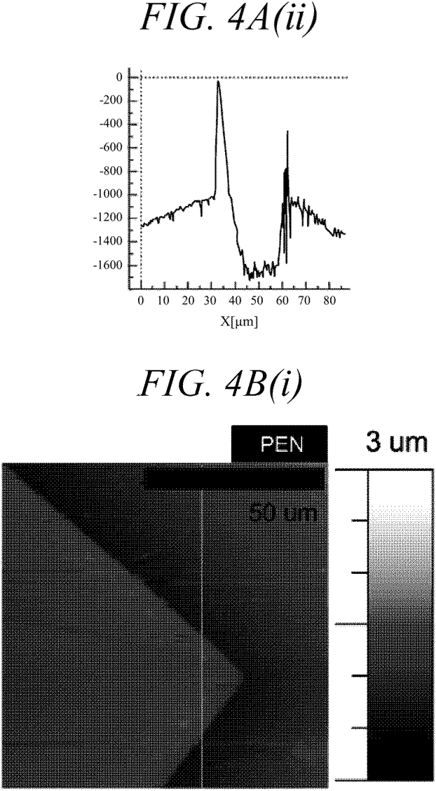

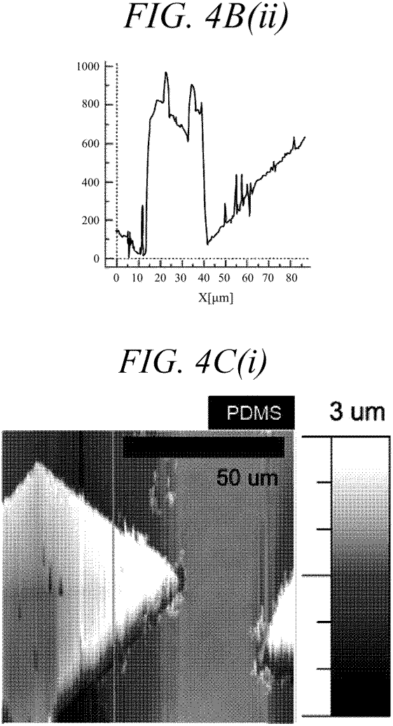

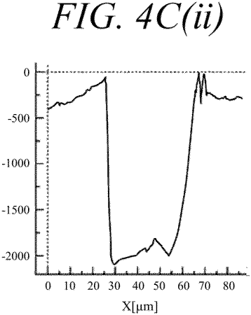

FIG. 2A to FIG. 2D are photographs of single crystal CH₃NH₃PbBr₃ halide perovskite grown on the flexible PI, PDMS, PTFE and PEN substrates, respectively, and orange-colored CH₃NH₃PbBr₃ single crystals can be seen with the naked eye from the photographs. Also, it was confirmed that the CH₃NH₃PbBr₃ single crystals did not fall off from the substrates even when the flexible substrates were bent. FIG. 3A(i) to FIG. 3D(ii) are micrographs of single crystal CH₃NH₃PbBr₃ halide perovskite grown on the flexible PI, PDMS, PTFE and PEN substrates, respectively. It was confirmed from the micrographs that the shapes and sizes of the grown crystals varied depending on the type of the flexible substrate. Also, it was confirmed that single crystals having a size of about 200 µm or more were grown on the flexible PI, PDMS and PEN substrates and a particle-shaped single crystal having a size of from about 5 µm to about 10 µm was grown on the flexible PTFE substrate. The particle-shaped single crystal grown on the flexible PTFE substrate can be applied as a base structure for a quantum dot device. FIG. 4A(i), FIG. 4B(i), and FIG. 4C(i) are topographic images of single crystal CH₃NH₃PbBr₃ halide perovskite grown on the flexible PI, PEN and PDMS substrates, respectively and FIG. 4A(ii), FIG. 4B(ii), and FIG. 4C(ii) are the thickness profiles for each line of FIG. 4A(i), FIG. 4B(i), and FIG. 4C(i), respectively. It was confirmed from the topographic images that single crystal CH₃NH₃PbBr₃ halide perovskite was grown to thicknesses of about 1.5 µm, about 0.8 µm and about 2 µm, respectively.

### <Example 2: Preparation of Single Crystal CH₃NH₃PbBr₃ Halide Perovskite on Flexible Polyimide (PI) Substrate>

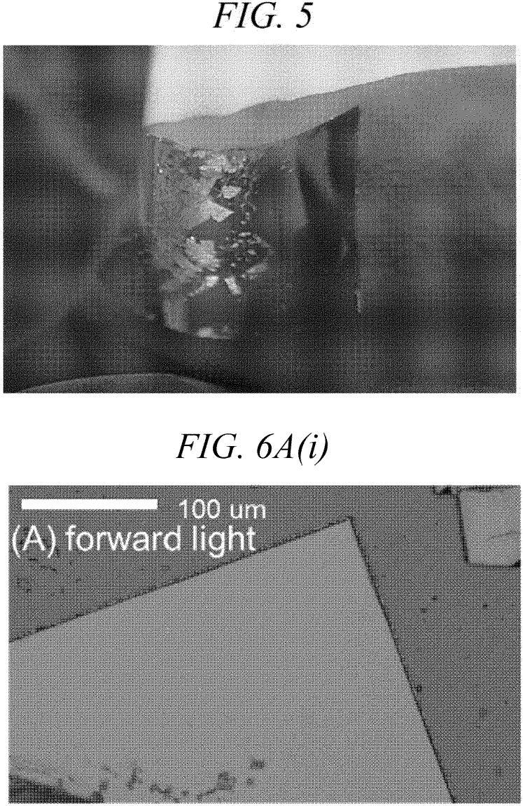

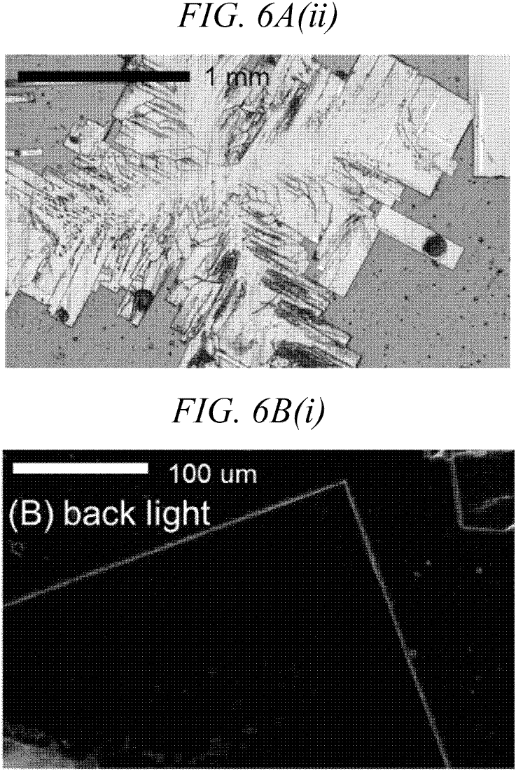

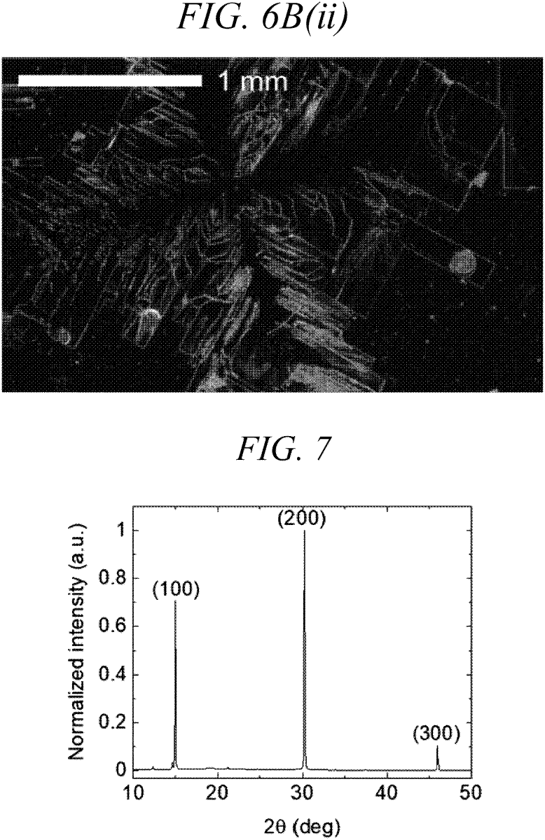

Based on the analysis results of Example 1, the flexible PI substrate was selected and further analyzed, which has the highest degree of binding between the substrate and the single crystal and is easy to wash and handle and thus the resulting single crystal perovskite can have many applications as a device. Single crystal CH₃NH₃PbBr₃ halide perovskite was prepared in the same manner as in Example 1, but the thickness of the single crystal was 5 µm by using a spacer having a thickness of 5 µm. A single crystal with an even surface and no cracks was prepared by applying a pressure to an upper part of the cover. Further, it was observed that the single crystal was cracked after the flexible substrate was bent (FIG. 5). Referring to FIG. 6A(i), FIG. 6A(ii), FIG. 6B(i), and FIG. 6B(ii), the cracked single crystal was observed after the flexible substrate was bent (FIG. 6A(ii) and FIG. 6B(ii)).

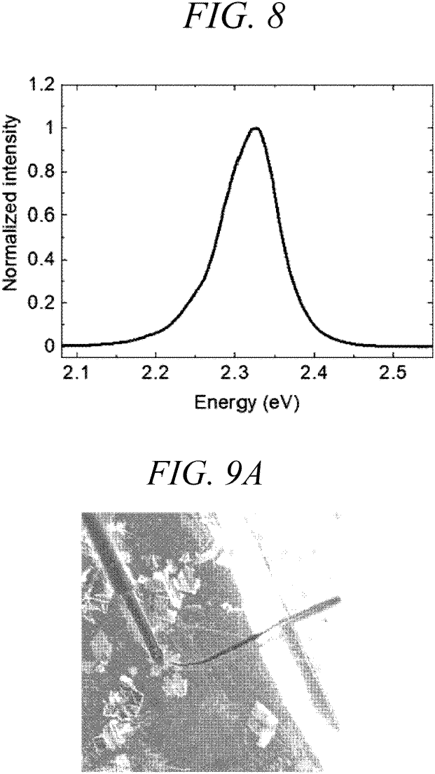

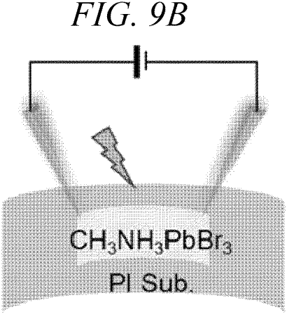

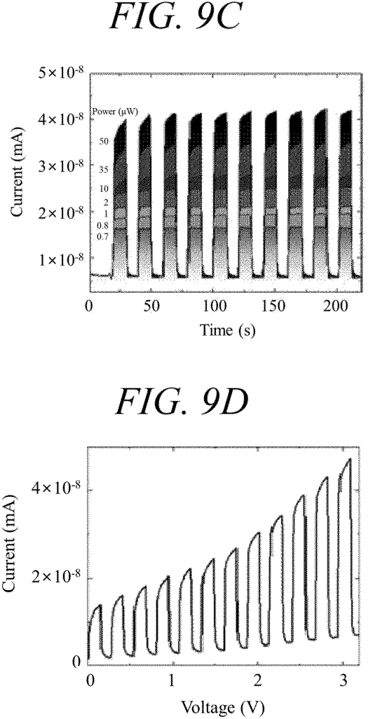

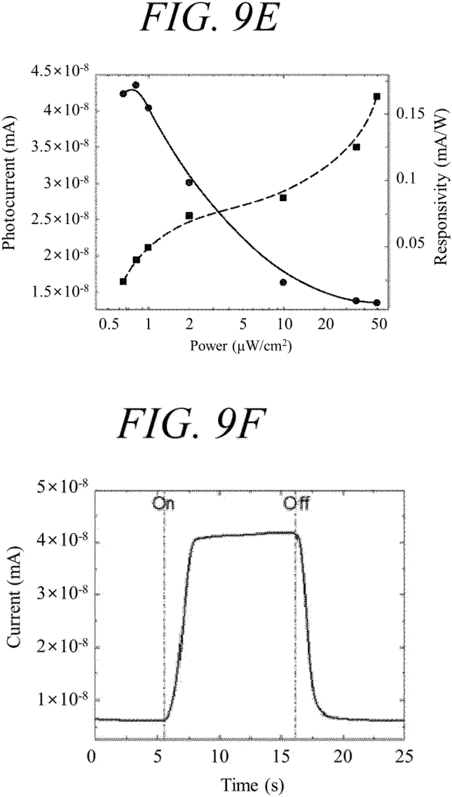

FIG. 7 and FIG. 8 show the X-ray diffraction (XRD) analysis result and the photoluminescence (PL) spectroscopy analysis result, respectively, of single crystal CH₃NH₃PbBr₃ halide perovskite. It was confirmed that the single crystal has a cubic structure with high crystallinity and has photon energy of 2.3 eV, which is similar to that of a bulk crystal. FIG. 9A and FIG. 9B show a micrograph showing a tip contact with single crystal perovskite and a schematic diagram for assessment of optoelectronic properties of crystal perovskite, respectively. FIG. 9C to FIG. 9F show results of assessment of optoelectronic properties of the single crystal. FIG. 9C shows a light on/off graph depending on the intensity of irradiated light, in which photocurrents were measured at a constant voltage of 2 V. FIG. 9D and FIG. 9E show a voltage-dependent photocurrent graph (FIG. 9D) and a light source power-dependent photocurrent and responsivity graph (FIG. 9E), respectively. FIG. 9F is an enlarged view of a one-cycle on/off graph at a light intensity of 5 µW. Referring to FIG. 9C to FIG. 9F, the photocurrent and light source power dependence caused by a wavelength of 405 nm was confirmed. Also, it was confirmed that high photoreactivity and device stability can be maintained even when a crack occurs in the single crystal. Accordingly, it was confirmed that, since the single crystal CH₃NH₃PbBr₃ halide perovskite is formed on the flexible substrate, it is not completely broken or cut even when a crack occurs.

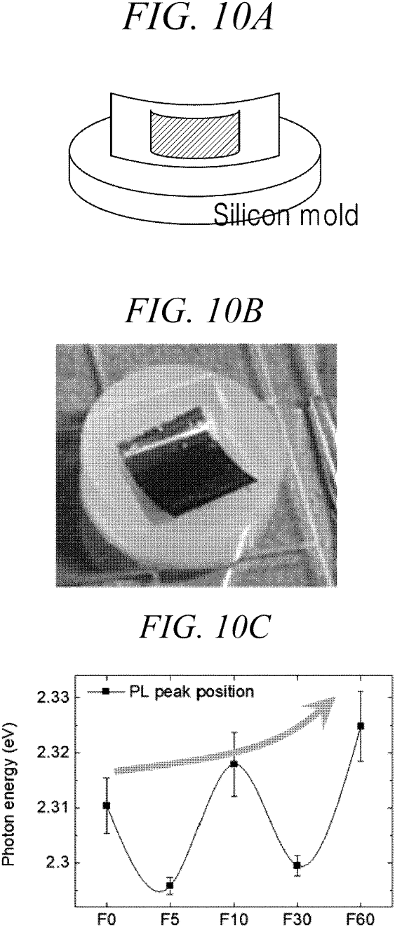

FIG. 10A and FIG. 10B are a schematic diagram (FIG. 10A) and a photograph (FIG. 10B) each showing that single crystal CH₃NH₃PbBr₃ halide perovskite grown on a flexible PI substrate is bent. FIG. 10C shows the PL spectroscopy analysis result of the single crystal when the flexible PI substrate was bent at 5°, 10°, 30° and 60° to assess the properties of the CH₃NH₃PbBr₃ single crystal depending on the flexibility. It was confirmed that as the bending angle increases, a value of photon energy obtained from the measurement of PL increases.

The above description of the present disclosure is provided for the purpose of illustration, and it would be understood by those skilled in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A method of preparing a single crystal perovskite, comprising:
applying a perovskite precursor solution onto a flexible substrate;
covering the perovskite precursor solution with a polymer cover; and
heat treating the perovskite precursor solution to grow the single crystal perovskite.

2. The method of claim 1,
wherein the flexible substrate includes at least one selected from polyimide (PI), polydimethylsiloxane (PDMS), polytetrafluoroethylene (PTFE), polyethylene naphthalate (PEN), polyethylene terephthalate (PET), and polyvinylidene-chloride (PVDC).

3. The method of claim 1,
wherein the flexible substrate includes a spacer formed on the flexible substrate.

4. The method of claim 3,
wherein the spacer includes at least one selected from polyimide (PI), polydimethylsiloxane (PDMS), polytetrafluoroethylene (PTFE), polyethylene naphthalate (PEN), polyethylene terephthalate (PET), and polyvinylidene-chloride (PVDC).

5. The method of claim 1,
wherein the polymer cover includes at least one selected from polyimide (PI), polydimethylsiloxane (PDMS), polytetrafluoroethylene (PTFE), polyethylene naphthalate (PEN), polyethylene terephthalate (PET), and polyvinylidene-chloride (PVDC).

6. The method of claim 1, further comprising:
applying a pressure to the polymer cover before the heat treating.

7. The method of claim 1,
wherein the heat treating is performed in a temperature range of 60° C. to 100° C.

8. The method of claim 1,
wherein the heat treating is performed in a pressure range of 0.5 bar to 1 bar.

9. A single crystal perovskite prepared by the method according to claim 1.

10. The single crystal perovskite of claim 9,
wherein the single crystal perovskite includes at least one selected from CH₃NH₃Pbl₃, CH₃NH₃PbBr₃, HC(NH₂)₂PbBr₃, HC(NH₂)₂Pbl₃, CH₃NH₃PbCl₃, HC(NH₂)₂PbCl₃, CsPbl₃, CsPbCl₃, CsPbBr₃, HC(NH₂)₂SnBr₃, HC(NH₂)₂SnBr₃, HC(NH₂)₂SnBr₃, CH₃NH₃SnBr₃, CH₃NH₃SnBr₃, and CH₃NH₃SnBr₃.

11. The single crystal perovskite of claim 9,
wherein the single crystal perovskite has a crystal size of 5 µm to 300 µm.

12. The single crystal perovskite of claim 9,
wherein the single crystal perovskite has a thickness of 0.5 µm to 20 µm.
